(19) United States
(12) Patent Application Publication
(10) Pub. No.: US 2022/0375908 A1
(43) Pub. Date: Nov. 24, 2022

(54) DISPLAY DEVICE AND DISPLAY PANEL PROVIDED THEREON

(71) Applicant: SAMSUNG ELECTRONICS CO., LTD., Suwon-si (KR)

(72) Inventors: Changjoon LEE, Suwon-si (KR); Wonsoon PARK, Suwon-si (KR); Seongho SON, Suwon-si (KR); Jongsung LEE, Suwon-si (KR); Chulyong JUNG, Suwon-si (KR)

(73) Assignee: SAMSUNG ELECTRONICS CO., LTD., Suwon-si (KR)

(21) Appl. No.: 17/881,238

(22) Filed: Aug. 4, 2022

Related U.S. Application Data
(63) Continuation of application No. PCT/KR2021/001890, filed on Feb. 15, 2021.

(30) Foreign Application Priority Data
Feb. 25, 2020 (KR) 10-2020-0022952

(51) Int. Cl. H01L 25/075; H01L 33/62; H01L 33/56; H01L 33/10; H01L 33/48; G02B 1/118

(52) U.S. Cl. CPC H01L 25/0753; H01L 33/62; H01L 33/56; H01L 33/10; H01L 33/486; G02B 1/118

(57) ABSTRACT

A display device includes a thin film transistor substrate including a mounting surface on which a plurality of electrode pads are formed, a plurality of inorganic light emitting device groups each forming a pixel and each including a plurality of inorganic light emitting devices respectively mounted on the mounting surface, and a mesh plate including a plurality of openings in which the plurality of inorganic light emitting device groups are respectively positioned, and a partition wall covering at least one portion of a non-mounted area between the plurality of inorganic light emitting device groups. The mesh plate includes an attaching surface facing the mounting surface and a reflective surface which is opposite the attaching surface. A moth eye pattern including a plurality of micro protrusions is formed on the reflective surface.

### CROSS-REFERENCE TO RELATED APPLICATION(S)

This application is by-pass continuation application of International Application No. PCT/KR2021/001890 filed on Feb. 15, 2021, which is based on and claims priority to Korean Patent Application No. 10-2020-0022952, filed on Feb. 25, 2020, in the Korean Intellectual Property Office, the disclosures of which are incorporated by reference herein in their entireties.

### BACKGROUND

### 1. Field

The disclosure relates to a display device for displaying images by combining display panels in which self-emissive inorganic light emitting devices are mounted on substrates.

### 2. Description of Related Art

A display device is an output device that visually displays images and data information, such as characters, figures, etc. Display devices include a television, a signage, a monitor, a notebook personal computer (PC), a tablet PC, a smart phone, etc.

As such a display device, a liquid crystal panel or an organic light emitting diode (OLED) panel formed by depositing OLEDs on substrates has been generally used. However, the liquid crystal panel has a slow response time, consumes a lot of power, is non-emissive, and requires a backlight, resulting in difficulties in achieving a compact size. Also, the OLED panel has a short life and causes a burn-in phenomenon due to use of organic materials vulnerable to light and heat.

Accordingly, as a new panel for substituting these, a micro LED panel in which inorganic light emitting devices are mounted on substrates and used as pixels is being studied. The micro LED panel has low power consumption and causes no burn-in phenomenon due to higher durability than the OLED.

Also, the micro LED panel can be manufactured with various resolutions and sizes by assembling unit panels.

### SUMMARY

Provided are a display panel capable of lowering screen reflectance and blocking light entering a gap between neighboring display panels to minimize seam recognition, and a display device having the display panel.

Additional aspects will be set forth in part in the description which follows and, in part, will be apparent from the description, or may be learned by practice of the presented embodiments.

According to an aspect of the present disclosure, a display panel may include a thin film transistor substrate including a mounting surface on which a plurality of electrode pads are formed, a plurality of inorganic light emitting device groups each forming a pixel and each including a plurality of inorganic light emitting devices respectively mounted on the mounting surface, and a mesh plate including a plurality of openings in which the plurality of inorganic light emitting device groups are respectively positioned, and a partition wall covering at least one portion of a non-mounted area between the plurality of inorganic light emitting device groups. The mesh plate may include an attaching surface facing the mounting surface and a reflective surface which is opposite the attaching surface. A moth eye pattern including a plurality of micro protrusions may be formed on the reflective surface.

The display panel may include an anisotropic conductive layer provided on the mounting surface and electrically connecting the plurality of inorganic light emitting devices to the thin film transistor substrate.

The mesh plate may be an anisotropic conductive layer provided on the mounting surface and electrically connecting the plurality of inorganic light emitting devices to the thin film transistor substrate. The anisotropic conductive layer may include an adhesive resin, and a conductive ball dispersed in the adhesive resin and surrounded by an insulating film.

The anisotropic conductive layer may be provided on an entire area of the mounting surface.

The mesh plate may include an Invar material.

A thickness of the mesh plate may be less than a height by which the plurality of inorganic light emitting devices protrude from the anisotropic conductive layer.

A surface of the mesh plate may include a black color.

Each of the plurality of micro protrusions may be in a shape of a cone or a polypyramid protruding from the reflective surface.

A length and a height of each of the plurality of micro protrusions may be from tens of nanometers to hundreds of nanometers.

Each of the plurality of inorganic light emitting devices may be in a shape of a flip chip including a body emitting light and a pair of device electrodes protruding from the body toward the mounting surface.

The pair of device electrodes of the plurality of inorganic light emitting devices may be electrically connected to electrode pads of the thin film transistor substrate through a solder bump, and the display panel may further include an optical transparent adhesive provided between the thin film transistor substrate and the mesh plate and configured to attach the mesh plate to the thin film transistor substrate.

The thin film transistor substrate may include a substrate including glass material, and a thin film transistor wiring layer formed on the substrate.

According to an embodiment of the disclosure, the display device may lower screen reflectance and minimize light entering a gap between display panels, thereby achieving a seamless effect.

Also, the display device may improve a contrast ratio and improve color expression and image quality accordingly.

Also, the display device may minimize thermal deformation of components and improve durability and reliability.

Also, processes of mounting inorganic light emitting devices and attaching a mesh plate may be easily performed.

### BRIEF DESCRIPTION OF DRAWINGS

The above and other aspects, features, and advantages of certain embodiments of the present disclosure will be more apparent from the following description taken in conjunction with the accompanying drawings, in which:

FIG. 1 is a diagram of a display device according to an embodiment of the disclosure;

FIG. 2 is a diagram of a plurality of display panels of the display device of FIG. 1 according to an embodiment of the disclosure;

FIG. 3 is a diagram of a display panel of the display device of FIG. 1, and separately shows a thin film transistor substrate and a mesh plate, according to an embodiment of the disclosure;

FIG. 4 is a diagram of a portion of the display device of FIG. 1, and shows a state in which a mesh plate is attached to a thin film transistor substrate, according to an embodiment of the disclosure;

FIG. 5 is a diagram of a cross-sectional view taken along line I-I of FIG. 4, according to an embodiment of the disclosure;

FIG. 6 is a diagram of a moth eye pattern formed on a reflective surface of a mesh plate according to an embodiment of the disclosure;

FIG. 7 is a diagram of portions at which a plurality of display panels according to an embodiment of the disclosure are adjacent to each other, according to an embodiment of the disclosure; and

FIG. 8 is a diagram of a display panel according to an embodiment of the disclosure.

### DETAILED DESCRIPTION

The embodiments described in the present disclosure are only the preferred embodiments of the disclosure, and are not intended to represent all the technical ideas of the disclosure. Thus, it is to be understood that various equivalents or modified examples, which may replace the embodiments described in the present disclosure, are included in the scope of right of the disclosure when filing the present application.

It is to be understood that the singular forms “a,” “an,” and “the” include plural referents unless the context clearly dictates otherwise. In the drawings, for easy understanding, the shapes and sizes of components are more or less exaggeratedly shown.

It will be understood that when the terms “includes,” “comprises,” “including,” and/or “comprising,” when used in this specification, specify the presence of stated features, figures, steps, operations, components, members, or combinations thereof, but do not preclude the presence or addition of one or more other features, figures, steps, operations, components, members, or combinations thereof.

Hereinafter, preferred embodiments of the disclosure will be described in detail with reference to the accompanying drawings.

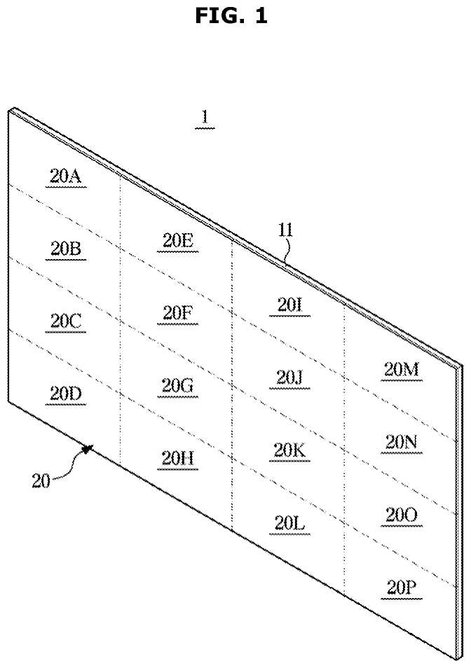

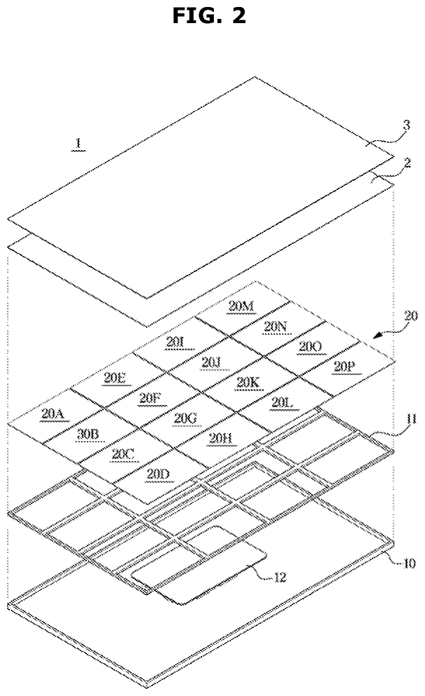

FIG. 1 is a diagram of a display device according to an embodiment of the disclosure. FIG. 2 is a diagram of a plurality of display panels of the display device of FIG. 1 according to an embodiment of the disclosure.

A display device 1 may be a device for displaying information, data, etc. as characters, figures, graphs, and images, and a television, a personal computer (PC), a mobile, a digital signage, etc. may be implemented as the display device 1.

The display device 1 may include a plurality of display panels 20A to 20P for displaying images, a frame 11 on which the display panels 20A to 20P are installed and supported, and a rear cover 10 covering a rear surface of the frame 11.

The plurality of display panels 20A to 20P may be adjacent to each other at upper, lower, left, and right sides. The plurality of display panels 20A to 20P may be arranged in a form of an M*N matrix. In the current embodiment, the plurality of display panels 20A to 20P may be 16 display panels arranged in a form of a 4*4 matrix. However, the number and arrangement of the plurality of display panels 20A to 20P are not limited. As such, the display device 1 according to an embodiment of the disclosure may implement a large screen by tiling a plurality of display panels.

The plurality of display panels 20A to 20P may have the same configuration. Hereinafter, the plurality of display panels 20A to 20P will be simply referred to as a display panel 20 as long as the plurality of display panels 20A to 20P need not to be distinguished from each other.

The plurality of display panels 20A to 20P may be mounted on the frame 21. The plurality of display panels 20A to 20P may be mounted on the frame 21 by various known methods using a magnet, a mechanical coupling member, etc. A shape and structure of the frame 21 are not limited as long as the frame 21 can support the plurality of display panels 20A to 20P.

The display device 1 may include a power supply for supplying power to the plurality of display panels 20A to 20P, a main board 12 for controlling the plurality of display panels 20A to 20P to display an image, a bracket for installing the display device 1 on a floor or wall, etc.

The display device 1 may include an encapsulation layer 2 provided in front of the plurality of display panels 20A to 20P to protect the plurality of display panels 20A to 20P and improve optical performance.

The encapsulation layer 2 may have a size corresponding to the entire screen of the display device 1. The encapsulation layer 2 may cover the entire of a front surface of the plurality of display panels 20A to 20P.

The encapsulation layer 2 may be formed of an optical transparent adhesive, such as an optical cleared adhesive (OCA) or an optical clear resin (OCR). The OCA and OCR may be a highly transparent material having transmittance of 90% or more.

The OCA and OCR may improve image quality because the OCA and OCR have high transmittance. That is, the OCA and OCR may be advantageous in view of image quality improvement, as well as bonding component layers with each other.

A front cover layer 3 may be provided in front of the encapsulation layer 2. The front cover layer 3 may be formed of glass, a film, or the like. The encapsulation layer 20 may perform various functions, such as adjusting light transmittance, anti-glare, and changing a phase of outside light, as well as protecting the display panel 20.

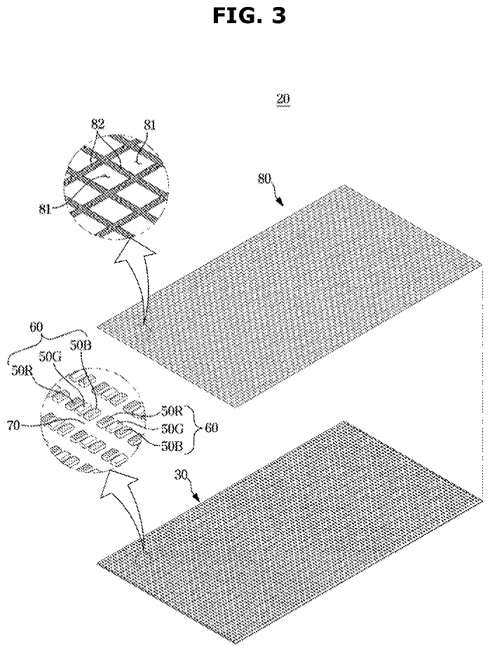

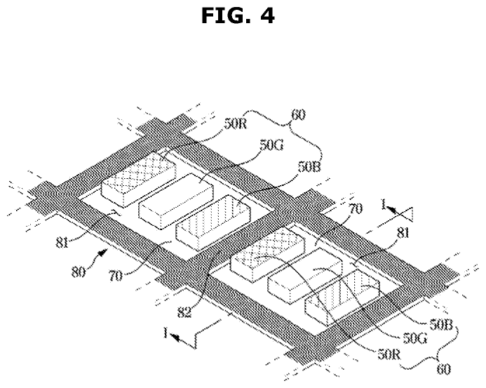

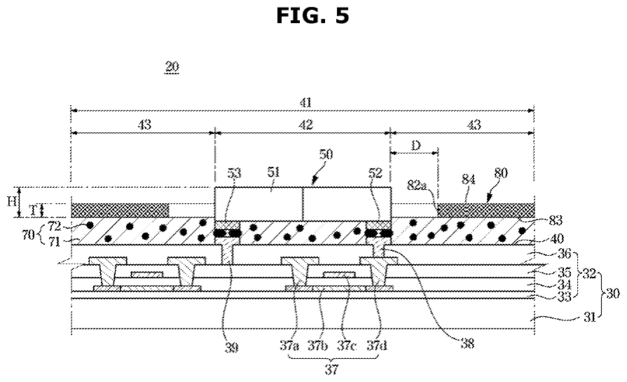

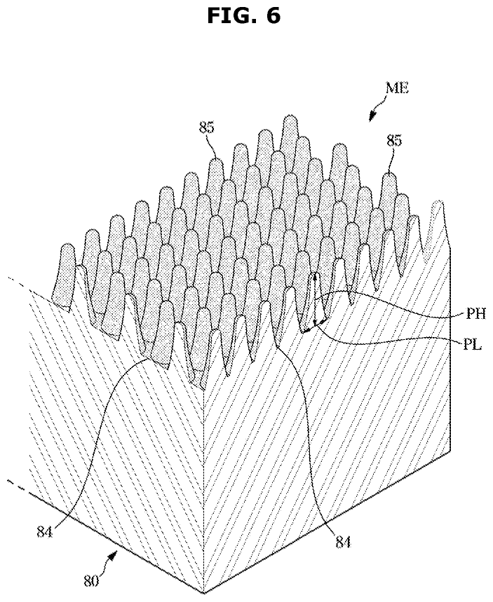

FIG. 3 is a diagram of a display panel of the display device of FIG. 1, and separately shows a thin film transistor substrate and a mesh plate, according to an embodiment of the disclosure. FIG. 4 is a diagram of a portion of the display device of FIG. 1, and shows a state in which a mesh plate is attached to a thin film transistor substrate, according to an embodiment of the disclosure. FIG. 5 is a diagram of a cross-sectional view taken along line I-I of FIG. 4, according to an embodiment of the disclosure. FIG. 6 is a diagram of a moth eye pattern formed on a reflective surface of a mesh plate according to an embodiment of the disclosure.

Hereinafter, a configuration of the display panel 20 according to an embodiment of the disclosure will be described in detail with reference to the drawings.

The display panel 20 may include a thin film transistor substrate 30 on which a plurality of inorganic light emitting devices 50 are mounted, and a mesh plate 80 having openings 81 and partition walls 82.

The thin film transistor substrate 30 may include a substrate 31, and a thin film transistor wiring layer 32 formed on the substrate 31 to drive the plurality of light emitting devices 50. The thin film transistor substrate 30 is also called a TFT array, a TFT panel, a TFT backplane, etc.

The substrate 31 may form a frame of the display panel 20 and may be formed of a glass material. However, in some cases, the substrate 31 may be formed of polyimide, PET, FR4, etc., instead of glass.

The thin film transistor wiring layer 32 may have a structure in which a plurality of sub pixel areas defined by data lines and scan lines are arranged in a form of a checkerboard. The plurality of sub pixel areas may include sub pixel areas of R, G, and B, and inorganic light emitting devices 50R, 50G, and 50B of R, G, and B may be respectively mounted on the sub pixel areas of R, G, and B. Each of the inorganic light emitting devices 50R, 50G, and 50B of R, G, and B may form a sub pixel, and light emitted from the inorganic light emitting devices 50R, 50G, and 50B of R, G, and B may be mixed to form a pixel. Hereinafter, the inorganic light emitting devices 50R, 50G, and 50B of R, G, and B are simply referred to as an inorganic light emitting device 50 as long as the inorganic light emitting devices 50R, 50G, and 50B of R, G, and B need not to be distinguished from each other.

One sub pixel area may include at least one thin film transistor 37 and a pair of electrode pads 38 and 39. The transistor 37 may include a source electrode 37a, an active layer 37b, a gate electrode 37c, and a drain electrode 37d.

The gate electrode 37c may function to allow current to flow or not flow through the active layer 37b, and the source electrode 37a and the drain electrode 37d may supply or receive electrons through the active layer 37b. The active layer 37b may be formed of a semiconductor, such as amorphous silicon (a-Si) or low temperature poly silicon (LTPS).

The thin film transistor wiring layer 32 may include a buffer layer 33 and a plurality of insulating layers 34, 35, and 36, and the buffer layer 33 may provide flatness on a front surface of the substrate 31 and prevent foreign materials or moisture from permeating into the substrate 31. The thin film transistor 37 may be positioned on the buffer layer 33.

The pair of electrode pads 38 and 39 may be formed on a mounting surface 40 of the thin film transistor 30, and may be electrically connected to a pair of device electrodes 52 and 53 of the inorganic light emitting device 50.

The inorganic light emitting device 50 may constitute a sub pixel, and have a size of tens of micrometers (μm) to hundreds of micrometers (μm) in width, length, and height. The inorganic light emitting device 50 may be formed by growing a compound semiconductor to a single crystal state at high temperature and high pressure on a parent substrate made of sapphire, gallium-arsenic (GaAs), or silicon (Si), and the inorganic light emitting device 50 may be configured to show different colors of red, green, blue, etc. according to a composition.

The inorganic light emitting device 50 may be picked up from the parent substrate and directly transferred to the thin film transistor substrate 30. The plurality of inorganic light emitting devices 50 may be picked up or conveyed by an electrostatic method using an electrostatic head, an adhesive method using a polymer material having elasticity, such as PDMS or silicon, as a head, or the like.

The inorganic light emitting device 50 may include a body 51 as a light emitting portion, and the pair of device electrodes 52 and 53 protruding from the body 51 to supply holes and electrons to the body 51.

The pair of device electrodes 52 and 53 may protrude in the same direction toward the mounting surface 40, and may be electrically connected to the pair of electrode pads 38 and 39 of the thin film transistor substrate 30 without any additional connection structure such as a wire. That is, the inorganic light emitting device 50 may be in a shape of a so-called flip chip.

The flip chip shape may require a simple processing operation, show excellent light emitting efficiency, and achieve a compact size, compared to a general lateral chip shape requiring wire bonding or a vertical chip shape requiring an additional operation of taking a sapphire substrate off.

A plurality of inorganic light emitting devices may form one pixel together, and a plurality of inorganic light emitting devices 50R, 50G, and 50C forming one pixel are referred to as an inorganic light emitting device group 60.

The inorganic light emitting device group 60 may include the inorganic light emitting devices 50R, 50G, and 50B of R, G, and B. However, unlike the current embodiment, the inorganic light emitting device group 60 may further include an inorganic light emitting device of W. The inorganic light emitting devices 50R, 50G, and 50B of R, G, and B may be aligned at preset intervals. However, unlike the current embodiment, the inorganic light emitting devices 50R, 50G, and 50B of R, G, and B may be arranged in a triangular shape or another shape.

The display panel 20 may further include an anisotropic conductive layer 70 provided on the mounting surface 40 to electrically connect the inorganic light emitting devices 50 to the thin film transistor substrate 30.

The anisotropic conductive layer 70 may have a structure in which a conductive adhesive made of an adhesive resin 71 with dispersed conductive balls 72 is surrounded by a protective film. The conductive balls 71 may be conductive spheres surrounded by thin insulating films, and the insulating films may be broken by heating and pressing to electrically connect conductors to each other. The conductive balls 72 may be formed of nickel (Ni), Carbon, Solder, etc.

The anisotropic conductive layer 70 may include an anisotropic conductive film (ACF) being in a shape of a film, and an anisotropic conductive paste (ACP) being in a form of a paste. The anisotropic conductive layer 70 may be provided on the entire area 41 of the mounting surface 40.

Upon mounting of the inorganic light emitting devices 50 on the thin film transistor substrate 30, heat and pressure may be applied to the anisotropic conductive layer 70 to break the insulating films of the conductive balls 72. Accordingly, the device electrodes 52 and 53 of the inorganic light emitting devices 50 may be electrically connected to the electrode pads 38 and 39 of the thin film transistor substrate 30.

The display panel 20 may include the mesh plate 80 having the plurality of openings 81 in which the inorganic light emitting device groups 60 are respectively positioned, and the partition walls 82 covering at least one portion of a non-mounted area 43 between the inorganic light emitting device groups 60 in the entire area 41 of the mounting surface 40. The non-mounted area 43 of the mounting surface 40 may be an area excepting a mounted area 42 occupied by the inorganic light emitting device groups 60 in the entire area 41 of the mounting surface 40.

That is, the mesh plate 80 may have a matrix form, and an inorganic light emitting device group 60 forming one pixel may be positioned in each opening 81.

The mesh plate 80 may include an attaching surface 83 facing the mounting surface 40, and a reflective surface 84 which is opposite to the attaching surface 83. The attaching surface 83 may be flat and smooth. However, the reflective surface 84 may be rough and uneven because the reflective surface 84 includes a moth eye pattern ME which will be described below.

The mesh plate 80 may be attached to the anisotropic conductive layer 70. The attaching surface 83 of the mesh plate 80 may be in contact with the anisotropic conductive layer 70. That is, the mesh plate 80 may be put on the anisotropic conductive layer 70 without using any additional adhesive member and then adhered directly to the anisotropic conductive layer 70 by heating and pressing.

That is, according to an embodiment of the disclosure, all of the inorganic light emitting devices 50 and the mesh plate 80 may be mounted on the thin film transistor substrate 30 through the anisotropic conductive layer 70. Accordingly, a process may be simplified and become easier.

The mesh plate 80 may have a uniform thickness T, and the thickness T of the mesh plate 80 may be smaller than a height H of the inorganic light emitting devices 50 protruding from the anisotropic conductive layer 70 to secure a viewing angle.

Also, sides 82a of the mesh plate 80, which face the inorganic light emitting devices 50, may be spaced a preset distance D from the inorganic light emitting devices 50 to secure a viewing angle and consider a level of difficulty in mounting the inorganic light emitting devices 50.

The openings 81 of the mesh plate 80 may be formed by Wet etching, Dry etching, Laser processing, or the like, and a size of each opening 81 may be 0.1 μm or more by considering a size of each inorganic light emitting device 50, a distance to the inorganic light emitting device 50, a viewing angle, etc.

In the present disclosure, the term ‘plate’ of the mesh plate 80 is not limited by a manufacturing process and a thickness. The term ‘plate’ may include all of ‘film’, ‘sheet’, or ‘plate’.

That is, a material that is manufactured by a stretching process according to a general manufacturing process is called a film and a material that is manufactured by an extruding process is called a sheet, or a material having a thickness of several millimeters or less is called a film and a material that is thicker than a film is called a sheet. Also, a material that is thicker than a sheet is called a plate. However, in the present disclosure, the term ‘plate’ may include all of such a ‘film’, ‘sheet’, or ‘plate’.

That is, the “mesh plate” of the present disclosure may include all of a film, a sheet, and a plate, which are in a form of a mesh.

The mesh plate 80 may be formed of a material with little change in temperature. In a case in which the substrate 31 of the thin film transistor substrate 30 is formed of a glass material having a small thermal expansion coefficient, it may be advantageous that the mesh plate 80 is also formed of a material having a small thermal expansion coefficient correspondingly. For example, the mesh plate 80 may be formed of an Invar material. The Invar is an alloy formed by adding nickel to iron, and has a small thermal expansion coefficient.

More specifically, the mesh plate 80 may be formed of a material having a thermal expansion coefficient of about ±2(10⁻⁶ K⁻¹)(20° C.), such as Invar, Super Invar, Stainless Invar, a NILO alloy, MEN PDS, MEN PB, DF 42N, VDF 47N, DF 52N, DF 16CN, etc.

A surface of the mesh plate 80 may be formed with a black color having an optical absorption effect. Accordingly, the mesh plate 80 may raise a contrast ratio of a screen, and minimize seam recognition that is caused by a gap G between display panels.

On the reflective surface 84 of the mesh plate 80, a moth eye pattern ME including a plurality of micro protrusions 85 may be formed. The moth eye pattern ME may scatter incident light to thereby lower reflectivity of the reflective surface 84. Because the reflectivity of the reflective surface 84 of the mesh plate 80 is lowered, black impression may be further raised, and seam recognition between the display panels may be further prevented.

Referring to FIG. 6, the moth eye pattern ME may include the plurality of micro protrusions 85 protruding from the reflective surface 84 of the mesh plate 80.

Each micro protrusion 85 may be in a shape of a cone. However, unlike the present embodiment, each micro protrusion 85 may be in a shape of a polypyramid such as a triangular pyramid. An upper end of a horn shape may be sharp or smooth.

The micro protrusions 85 may be formed in a nano scale. That is, a length PL and a height PH of the micro protrusions 85 may have values between tens of nanometers and hundreds of nanometers.

The micro protrusions 85 may be formed continuously or discontinuously. Intervals between the micro protrusions 85 may also be between tens of nanometers and hundreds of nanometers, and the micro protrusions 85 may need not to be arranged at regular intervals.

Reflectivity of the reflective surface 84 of the mesh plate may be lowered by the moth eye pattern ME. A principle of anti-reflection by the moth eye pattern ME may be as follows.

Reflection of light is greatly generated according to a sharp change of a refractive index, whereas a gradual change of a refractive index may reduce reflection of light. In the case of a micro structure with a smaller size than a diffraction limit, light cannot recognize details of the structure, and may recognize characteristics of a composite medium composed of the micro structure and air as characteristics of a homogenous medium.

That is, because the micro protrusions 85 occupy greater areas at closer locations to the reflective surface 84 of the mesh plate 80 from outside of the reflective surface 84, differences between reflective indexes may be gradually reduced. Accordingly, due to such characteristics of light, reflection of light may be minimized by the moth eye pattern ME.

The micro protrusions 85 may be integrated into the mesh plate 80 by an electroforming method upon molding of the mesh plate 80.

The electroforming method may be a method of electro-depositing a metal on a model to which a release coating is applied and separating the electro-deposited metal to obtain a product with a concave-convex surface that is inverted from the surface of the model, or a method of performing release coating processing on a product, electro-depositing a metal thereon, and then separating the electro-deposited metal to obtain a product with the same concave-convex surface as the original model.

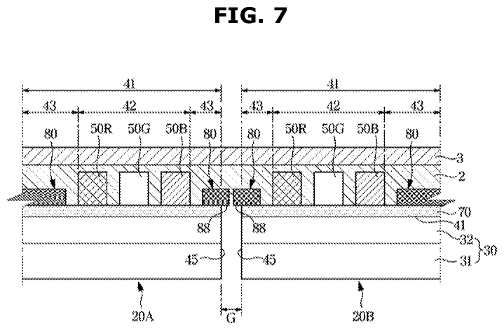

FIG. 7 is a diagram of portions at which a plurality of display panels according to an embodiment of the disclosure are adjacent to each other, according to an embodiment of the disclosure.

According to an embodiment of the disclosure, the mesh plate 80 may be provided for each display panel 20. Accordingly, a plurality of mesh plates 80 respectively provided in the plurality of display panels 20 may be spaced from each other.

For example, as shown in FIG. 7, a gap G may be formed between a plurality of neighboring display panels 20A and 20B, and accordingly, a mesh plate 80 included in the display panel 20A may also be spaced from a mesh plate 80 included in the display panel 20B.

However, according to an embodiment of the disclosure, the mesh plate 80 may include an extension portion 88 extending from a side surface 45 of the thin film transistor substrate 30 toward the gap G.

Light entering the gap G may be minimized by the extension portion 88 of the mesh plate 80, and accordingly, diffused reflection of light at the gap G may be minimized to prevent seam recognition, degradation of image quality, sense-of-difference formation, etc.

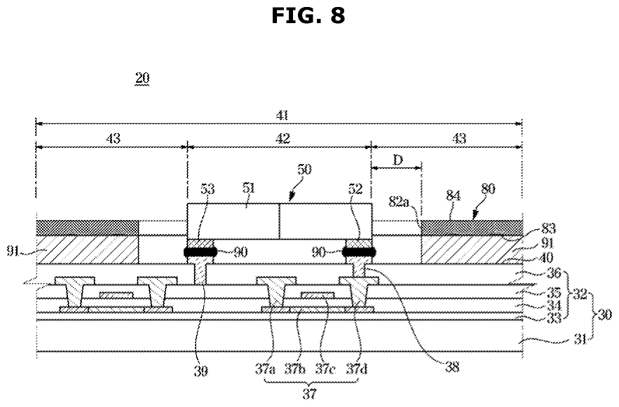

FIG. 8 is a diagram of a display panel according to an embodiment of the disclosure.

A display panel according to another embodiment of the disclosure will be described with reference to FIG. 8. The same components as those of the above-described embodiment will be assigned the same reference numerals, and descriptions about the components will be omitted.

According to another embodiment of the disclosure, no anisotropic conductive layer may be provided in the display panel 20, and the inorganic light emitting device 50 may be mounted on the mounting surface 40 of the thin film transistor substrate 30 through a solder bump 90, instead of an anisotropic conductive layer.

The solder bump 90 may be a conductive melting material, and may be positioned between the device electrodes 52 and 53 of the inorganic light emitting device 50 and the electrode pads 38 and 39 of the thin film transistor substrate 30. The device electrodes 52 and 53 of the inorganic light emitting device 50 may be arranged to correspond to the electrode pads 38 and 39 of the thin film transistor substrate 30, a reflow process may be performed, and thereby, the inorganic light emitting device 50 may be electrically connected to the thin film transistor substrate 30.

At this time, the mesh plate 80 may be attached to the thin film transistor substrate 30 through a separate optical transparent adhesive 91. As the optical transparent adhesive 91, an OCA film or an OCR may be used.

Although the technical concept of the disclosure has been described based on specific embodiments, the scope of rights of the disclosure is not limited to these embodiments. It should be interpreted that various embodiments modified or changed by a person skilled in the art within a scope not deviating from the gist of the disclosure as the technical concept of the disclosure, which is defined in the claims, also belong to the scope of rights of the disclosure.

What is claimed is:

1. A display panel comprising:
a thin film transistor substrate comprising a mounting surface on which a plurality of electrode pads are formed;
a plurality of inorganic light emitting device groups each forming a pixel and each comprising a plurality of inorganic light emitting devices respectively mounted on the mounting surface; and
a mesh plate comprising:
a plurality of openings in which the plurality of inorganic light emitting device groups are respectively positioned, and
a partition wall covering at least one portion of a non-mounted area between the plurality of inorganic light emitting device groups,
wherein the mesh plate comprises an attaching surface facing the mounting surface, and a reflective surface which is opposite the attaching surface, and
wherein a moth eye pattern comprising a plurality of micro protrusions is formed on the reflective surface.

2. The display panel of claim 1, further comprising an anisotropic conductive layer provided on the mounting surface and electrically connecting the plurality of inorganic light emitting devices to the thin film transistor substrate.

3. The display panel of claim 2, wherein the mesh plate is configured to be attached to the anisotropic conductive layer such that the attaching surface is in contact with the anisotropic conductive layer.

4. The display panel of claim 2, wherein the anisotropic conductive layer comprises an adhesive resin, and a conductive ball dispersed in the adhesive resin and surrounded by an insulating film.

5. The display panel of claim 2, wherein the anisotropic conductive layer is provided on an entire area of the mounting surface.

6. The display panel of claim 1, wherein the mesh plate comprises an Invar material.

7. The display panel of claim 2, wherein a thickness of the mesh plate is less than a height by which the plurality of inorganic light emitting devices protrude from the anisotropic conductive layer.

8. The display panel of claim 1, wherein a surface of the mesh plate comprises a black color.

9. The display panel of claim 1, wherein each of the plurality of micro protrusions is in a shape of a cone or a polypyramid protruding from the reflective surface.

10. The display panel of claim 1, wherein a length and a height of each of the plurality of micro protrusions are from tens of nanometers to hundreds of nanometers.

11. The display panel of claim 1, wherein each of the plurality of inorganic light emitting devices is in a shape of a flip chip comprising a body emitting light and a pair of device electrodes protruding from the body toward the mounting surface.

12. The display panel of claim 11, wherein the pair of device electrodes of the plurality of inorganic light emitting devices are electrically connected to electrode pads of the thin film transistor substrate through a solder bump, and
wherein the display panel further comprises an optical transparent adhesive provided between the thin film transistor substrate and the mesh plate and configured to attach the mesh plate to the thin film transistor substrate.

13. The display panel of claim 1, wherein the thin film transistor substrate comprises:
a substrate comprising glass material; and
a thin film transistor wiring layer formed on the substrate.
